(19) United States
(12) Patent Application Publication
(10) Pub. No.: US 2026/0266926 A1
(43) Pub. Date: Sep. 10, 2026

(54) METHOD FOR MEASURING TRANSFORMER LEAKAGE MAGNETIC FIELD SIGNALS BASED ON IMPROVED SVMD COMBINED WITH WAVELET THRESHOLD METHOD

(71) Applicant: Sanmen Nuclear Power Co., Ltd., Taizhou (CN)

(72) Inventors: Qiuyang LIN, Taizhou (CN); Fengping ZHANG, Taizhou (CN); Congwei WANG, Taizhou (CN); Luyi ZHANG, Taizhou (CN); Zichi ZHAO, Taizhou (CN); Jiaqi LIU, Taizhou (CN); Shiqing FANG, Taizhou (CN); Zhi LI, Taizhou (CN)

(21) Appl. No.: 19/565,978

(22) Filed: Mar. 13, 2026

Related U.S. Application Data
(63) Continuation-in-part of application No. PCT/CN2025/098447, filed on May 30, 2025.

(30) Foreign Application Priority Data
Mar. 5, 2025 (CN) 202510255888.1

(51) Int. Cl. G01R 33/032; G01R 31/62; G01R 33/00; G06F 17/14

(52) U.S. Cl. CPC G01R 33/032; G01R 31/62; G01R 33/0029; G06F 17/148

(57) ABSTRACT

The present disclosure relates to the technical field of detection for leakage magnetic field of a transformer in an electric power system, and particularly to a method for measuring transformer leakage magnetic field signals based on improved SVMD combined with a wavelet threshold method. The method includes: Step 1: determining a parameter of the SVMD parameter through a NRBO; Step 2: performing, on the basis of the Step 1, an SVMD on a leakage magnetic field signal measured by a magneto-optical sensor; and Step 3: further processing residual noise in the signal in conjunction with a wavelet threshold method.

### CROSS-REFERENCE TO RELATED APPLICATIONS

The present disclosure is a continuation of International Patent Application No. PCT/CN2025/098447 filed on May 30, 2025, which claims priority to Chinese Patent Application No. 202510255888.1 filed on Mar. 5, 2025, both of which are herein incorporated by reference in their entireties.

### TECHNICAL FIELD

The present disclosure relates to the technical field of detection of leakage magnetic field of a transformer in an electric power system, and particularly to a method for measuring transformer leakage magnetic field signals based on improved Successive Variational Mode Decomposition (SVMD) combined with a wavelet threshold method.

### BACKGROUND

With the gradual development of Chinese new-type electric power systems and ultra-high voltage power grids, the operating environment of transformers has grown increasingly diverse and sophisticated. During the operation of a transformer, windings may be subjected to impacts exerted by a short-circuit electromagnetic force, which causes permanent deformations such as displacement, depression, or bulging of the windings, thereby severely impairing the inter-turn insulation of the windings and raises the likelihood of winding faults. At present, transformer fault detection methods are mainly classified into offline detection methods and online detection methods. The offline detection methods, such as a short-circuit reactance method and a frequency response method, have relatively mature technologies, but they need to be carried out during transformer maintenance and are incapable of real-time monitoring or timely fault identification. Among the online detection methods, a vibration method fails to formulate distinct criteria for quantifying the fault severity, while a parameter identification method has problems such as low computational accuracy of parameters and ambiguous correlation between parameters and faults. The above methods have shortcomings in identifying the faults of transformer windings. Studies have shown that when there are latent faults of transformer windings, the distribution of a leakage magnetic field around the windings will vary and exhibit a definite regularity, which provides a new research approach for diagnosing the faults of transformer windings by utilizing the variations in the distribution of the leakage magnetic field.

Although transformer leakage magnetic field signals can reflect the operating status of a transformer to a substantial degree, the vast majority of relevant analyses are performed under idealized conditions, without giving adequate consideration to the noise and harmonic interference that may exist in actual measurement processes. Due to the presence of these interfering signals, the accuracy of fault diagnosis will be significantly reduced if the untreated magnetic leakage signals are directly used for fault diagnosis.

### SUMMARY

The present disclosure aims to provide a method for measuring transformer leakage magnetic field signals based on improved Successive Variational Mode Decomposition (SVMD) combined with a wavelet threshold method, which performs efficient denoising processing of practically measured leakage magnetic field signals, and is key to improving the accuracy of fault diagnosis. By combining the advantages of the improved SVMD and the wavelet threshold method, the present disclosure can effectively eliminate noise interference and extract key features, thereby providing a reliable basis for the accurate fault diagnosis of transformer windings.

The technical solution of the present disclosure is as follows: a method for measuring transformer leakage magnetic field signals based on improved Successive Variational Mode Decomposition (SVMD) combined with a wavelet threshold method, including:
Step 1: determining a parameter of Successive Variational Mode Decomposition (SVMD) through a Newton-Raphson-Based Optimizer (NRBO);
Step 2: performing, on the basis of the Step 1, an SVMD on a leakage magnetic field signal measured by a magneto-optical sensor; and
Step 3: further processing residual noise in the signal in conjunction with a wavelet threshold method.

In the Step 1, a Newton-Raphson Search Rule (NRSR) is used to calculate a gradient and second-order information of a fitness function, and the fitness function adopts minimum fuzzy entropy, which serves as an objective function for optimization and is calculated in each iteration, a fuzzy entropy, as the fitness function, is capable of measuring the fuzziness degree of a signal decomposition result, and a minimized entropy value represents an optimal quality of decomposition; in each iteration, the NRBO adjusts αₘₐₓ according to a current fitness function value through the NRSR, so as to improve an accuracy of the decomposition result; finally, through the iterative optimization of the NRBO combined with the minimum fuzzy entropy fitness function, an optimal value of αₘₐₓ is obtained, so as to ensure an optimal quality of an SVMD result and improve the accuracy and the robustness of signal processing.

In the Step 1, the fuzzy entropy integrates a sample entropy and a fuzzy membership function to describe a signal complexity, and a more accurate signal description is provided by virtue of introducing the fuzzy membership function; assuming that the leakage magnetic field signal of a transformer winding measured by the magneto-optical sensor is an E-dimensional time series {l(t)=l(1), l(2), . . . , l(E)}, a time series D(i) is obtained after spatial reconstruction:

$$D ( i ) = [ l ( i ) , l ( i + 1 ) , … l ( i + a - 1 ) ] - {l}_{0} ( i ) \qquad ( 1 )$$

$${l}_{0} ( i ) = \frac{1}{a} {\sum }_{j = 0}^{a - 1} l ( i + j ) \qquad ( 2 )$$

where i=1, 2, . . . , E−a+1, and a denotes an embedding dimension; i and j denote index offsets of a time series; and l₀(i) denotes an average value;
next, a distance d between two time series D(i) and D(j) is defined in the following formula, which takes a maximum value of element-wise differences between the two time series:

$$\begin{matrix}{d}_{i , j}^{a} = d [ D ( i ) , D ( j ) ] \\ = {max}_{g = 0 , … , a - 1} \vert ( l ( i + g ) - {l}_{0} ( i ) - ( l ( j + g ) - {l}_{0} ( j ) ) \vert\end{matrix} \qquad ( 3 )$$

where d denotes the distance between the time series D(i) and D(j); and g denotes an index offset of the time series;
a similarity between the time series D(i) and D(j) is calculated using the fuzzy membership function:

$${F}_{i . j}^{a} = exp [ - \frac{{( {d}_{i . j}^{a} )}^{2}}{p} ] \qquad ( 4 )$$

where p denotes a similarity tolerance, which generally takes 0.15 times the standard deviation of an original leakage magnetic field signal; i, j=1, 2, . . . , E−a+1, and i≠j;

$${ψ}^{a} ( p ) = \frac{1}{E - a + 1} {{\sum }_{i = 1}}^{E - a + 1} ( \frac{1}{E - a} {\sum }_{j = 1 , j \neq i}^{E - a + 1} {F}_{i , j}^{a} ) \qquad ( 5 )$$

where ψ^{a}(p) denotes a metric value of a fuzzy similarity of the time series under a scale a;
then, the expression of the fuzzy entropy FuzzyEn(a, p, E) is:

$$FuzzyEn ( a , p , E ) = ln {ψ}^{a} ( p ) - ln {ψ}^{a + 1} ( p ) \qquad ( 6 )$$

upon calculation of the fuzzy entropy, the value of the entropy is used to guide an optimization process of a maximum penalty factor αₘₐₓ; through an optimization algorithm of the NRBO, in each iteration, the decomposition result is first calculated according to the current αₘₐₓ, then the corresponding fuzzy entropy value is determined and taken as the fitness function to adjust αₘₐₓ; and in each iteration, the NRBO updates αₘₐₓ according to the current fuzzy entropy value and the NRSR, so that the fuzzy entropy decreases gradually and eventually converge to a minimum value.

In the Step 2, the performing, on the basis of the Step 1, an SVMD on the leakage magnetic field signal measured by the magneto-optical sensor comprises: performing an SVMD on the leakage magnetic field signal l(t) measured by the magneto-optical sensor using the optimized αₘₐₓ.

In the Step 2, the SVMD divides l(t) into a plurality of mode functions; in each iteration, the SVMD updates the mode function by minimizing the difference between l(t) and the mode function, which is repeated continuously until convergence is achieved, and the finally obtained mode function is used to reconstruct an original signal.

In the Step 2, some constraints are imposed during the extraction of the mode function to prevent a model from converging to a mode having been extracted, and a constraint model is as follows:

$$\{ \begin{matrix}{min}_{\{ {u}_{M} \} , \{ {ω}_{M} \} , \{ {l}_{r} \}} \{ α {J}_{1} + {J}_{2} + {J}_{3} \} \\ s . t . {\sum }_{k = 1}^{K} {u}_{M} ( t ) + {l}_{r} ( t ) = l ( t )\end{matrix} \qquad ( 7 )$$

where J₁, J₂ and J₃ are three constraint criteria; a is a parameter used to balance J₁, J₂ and J₃, and is obtained by Lagrange multiplication, with a value less than αₘₐₓ; u_{M} denotes an M-th mode component decomposed through the SVMD; ω_{M} denotes a center frequency of an M-th mode; and lᵣ denotes a residual signal, i.e., an input signal excluding u_{M};
an augmented Lagrangian function is constructed as follows by introducing a combination of a quadratic penalty coefficient and a Lagrange multiplier λ:

$$L ( \{ {u}_{M} \} , \{ {ω}_{M} \} , λ ) = α {J}_{1} + {J}_{2} + {J}_{3} + {‖ l ( t ) - ( {u}_{M} ( t ) + {l}_{u} ( t ) + {\sum }_{i = 1}^{M - 1} {u}_{i} ( t ) ) ‖}_{2}^{2} + 〈 λ ( t ) , l ( t ) - ( {u}_{M} ( t ) + {l}_{u} ( t ) + {\sum }_{i = 1}^{M - 1} {u}_{i} ( t ) ) 〉 \qquad ( 8 )$$

similar to a Variational Mode Decomposition (VMD), the issue of minimization in Equation (8) is solved by iteratively using a Parseval's identity and an alternating direction method of multipliers, and specifically

$${\hat{u}}_{M}^{n + 1} ( ω ) = \frac{\hat{l} ( ω ) + {{α}^{2} ( ω - {ω}_{M}^{n} )}^{4} {\hat{u}}_{M}^{n} ( ω ) + \frac{\hat{λ} ( ω )}{2}}{A [ 1 + 2 {α ( ω - {ω}_{M}^{n} )}^{2} + {\sum }_{i - 1}^{M - 1} \frac{1}{{{α}^{2} ( ω - {ω}_{i} )}^{4}} ]} \qquad ( 9 )$$

$$A = 1 + {{α}^{2} ( ω - {ω}_{M}^{n} )}^{4} \qquad ( 10 )$$

where û_{M}(ω) denotes a frequency spectrum of the mode; l(ω) denotes a frequency spectrum of the signal; and n denotes the number of iterations;
Equation (11) is used to update the Lagrange multiplier:

$${\hat{λ}}^{n + 1} = {\hat{λ}}^{n} + τ [ \hat{l} ( ω ) - ( {\hat{u}}_{M}^{n + 1} ( ω ) + {l}_{u}^{n + 1} ( t ) + {\sum }_{i = 1}^{M - 1} {u}_{i}^{n + 1} ( ω ) ) ] \qquad ( 11 )$$

during the iteration, the center frequency and a bandwidth of an intrinsic mode function are updated continuously until the following conditions are met:

$$\{ \begin{matrix}\frac{{‖ {\hat{u}}_{M}^{n + 1} - {\hat{u}}_{M}^{n} ‖}_{2}^{2}}{‖ {\hat{u}}_{M}^{n} ‖} < {ε}_{1} \\ {σ}^{2} - \frac{1}{T} {‖ ( l ( t ) - {\sum }_{m = 1 : M} {u}_{m} ( t ) ) ‖}_{2}^{2} / {σ}^{2} < {ε}_{2}\end{matrix} \qquad ( 12 )$$

where

$${u}_{M}^{n}$$

denotes an n-th update of the M-th mode; T denotes a dual ascent time step; ε₁ and ε₂ denote tolerances; and σ² denotes a noise variance.

In the Step 3, the further processing residual noise in the signal in conjunction with the wavelet threshold method includes: performing a wavelet transform on the mode components and an residual signal lᵣ(t) obtained through the SVMD in the Step 2, so as to obtain a wavelet coefficient, and the wavelet transform can effectively decompose the signal into different frequency bands; and a soft-thresholding method is adopted for noise suppression, which is expressed as:

$${w}_{β , η}^{′} = \{ \begin{matrix}sgn ( {w}_{β , η} ) ( \vert {w}_{β , η} \vert - θ ) & \vert {w}_{β , η} \vert \geq θ \\ 0 & \vert {w}_{β , η} \vert < θ\end{matrix} \qquad ( 13 )$$

where sgn denotes a signum function; β denotes a variation factor; θ denotes a threshold parameter; w_{β,η} denotes an original wavelet coefficient of the signal; and w′_{β,η} denotes a processed wavelet coefficient of the signal;
and the threshold parameter θ is expressed as:

$$θ = μ \sqrt{2 ln N} \qquad ( 14 )$$

$$μ = \frac{median ( \vert {w}_{1 , η} \vert )}{0.6475} \qquad ( 15 )$$

where μ denotes a noise standard deviation; N denotes a signal length; median denotes a median absolute deviation; and w_{1,η} denotes an η-th wavelet coefficient in a first layer.

The present disclosure achieves the following advantageous effects: through an optimization algorithm of the NRBO, in each iteration, the decomposition result is first calculated according to the current αₘₐₓ, then the corresponding fuzzy entropy value is calculated and taken as the fitness function to adjust αₘₐₓ. In each iteration, the NRBO updates αₘₐₓ according to the current value of the fuzzy entropy and the NRSR, such that the fuzzy entropy decreases gradually and eventually converge to a minimum value. During this process, the Trap Avoidance Operator (TAO) helps the algorithm to escape from local optimal solutions, thereby ensuring that a globally optimal value of αₘₐₓ can be found. Through the continuous optimization of the fuzzy entropy, the NRBO finally determines the optimal αₘₐₓ that renders the optimal mode decomposition effect of the signal. After iteration and optimization by the SVMD algorithm, several mode components u_{M}(t) are finally obtained, which represent the independent components of the leakage magnetic field signal l(t) distributed within different frequency ranges. After optimization and constraint processing, each mode function u_{M}(t) can accurately represent the features of the signal, thereby facilitating in-depth analysis and fault diagnosis of the leakage magnetic field signal of the transformer windings. After the threshold processing of the wavelet coefficient, an inverse wavelet transform is adopted to reconstruct the processed coefficient into a time-domain signal. After the processing with the wavelet threshold method, the finally obtained signal has higher accuracy and lower noise compared with the original signal, making it suitable for further analysis and fault diagnosis.

### BRIEF DESCRIPTION OF THE DRAWINGS

FIG. 1 illustrates a flowchart of a method for measuring transformer leakage magnetic field signals based on improved SVMD combined with a wavelet threshold method according to the present disclosure; and

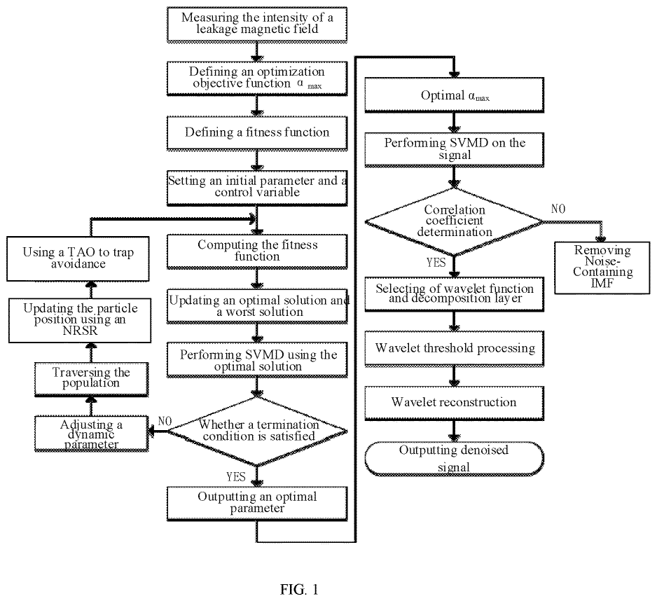

FIG. 2 illustrates a flowchart of determining an SVMD parameter αₘₐₓ via an NRBO.

### DESCRIPTION OF THE EMBODIMENTS

The present disclosure will be further described in detail below with reference to the drawings and the specific embodiments.

A method for measuring transformer leakage magnetic field signals based on improved sparsity-variational mode decomposition (SVMD) combined with a wavelet threshold method includes the following steps:

Step 1: determining a parameter of the SVMD through a Newton-Raphson-Based Optimizer (NRBO);

In the Step 1, the SVMD parameter is determined via the NRBO. As a signal decomposition method, the SVMD aims to extract different intrinsic mode functions (IMFs) from complex signals. Through IMF decomposition, high-frequency components containing noise and low-frequency components containing useful signals can be separated. The high-frequency noise components are removed and the important signal components are retained, which helps to improve the quality of signal processing. Compared with the traditional decomposition methods, the SVMD performs excellently in processing non-linear and non-stationary signals. As an extension of a Variational Mode Decomposition (VMD) method, the SVMD gradually extracts different modes from the signals by introducing a sequential variational optimization scheme.

In the VMD theory, the decomposition result is predominantly governed by the decompositions number k and the quadratic penalty factor α. However, in the SVMD theory, there is no need to ascertain the total number k of modes in the signal in advance. Therefore, the most critical parameter in the SVMD is a maximum penalty factor αₘₐₓ.

When αₘₐₓ is set too high, the regularization penalty is excessively strong, which leads to a large number of incorrect modes in the decomposition result; and when αₘₐₓ is set too low, the regularization penalty is insufficient, which causes a plurality of authentic modes to be erroneously merged into one or several modes, which is known as a mode mixing problem.

In the conventional methods, the determination of αₘₐₓ usually relies on a cross-validation method, a trial-and-error method, or the like. αₘₐₓ is iteratively adjusted, the decomposition effect is observed, and then adjustments are made based on the results. Although these methods are effective, their processes are cumbersome and require a large number of experimental adjustments, and they are susceptible to the influence of human factors. To address the above problems, the present disclosure adopts an NRBO to optimize αₘₐₓ.

The NRBO is a search algorithm inspired by the Newton-Raphson method. It employs a Newton-Raphson Search Rule (NRSR), a Trap Avoidance Operator (TAO), and several sets of matrices to explore the entire search process, thereby obtaining an optimal result. The NRSR enhances the exploration capability of the NRBO by using the Newton-Raphson method and accelerates the convergence speed, and the TAO helps the NRBO to avoid the problem of local optima.

Specifically, a gradient and second-order information of a fitness function is calculated using the NRSR, thereby enhancing the exploration capability of the NRBO and accelerating the convergence speed. In this technology, the minimum fuzzy entropy is adopted as the fitness function, which serves as an optimization objective function and is calculated in each iteration. As the fitness function, the fuzzy entropy can measure the fuzziness degree of a signal decomposition result, and a minimized entropy value represents an optimal quality of decomposition.

In each iteration, the NRBO uses the NRSR to adjust αₘₐₓ according to the current fitness function value (the minimum fuzzy entropy), thereby improving the accuracy of the decomposition result. If the fitness function value caused by the current αₘₐₓ is poor, the NRBO will adjust αₘₐₓ to improve the quality of mode decomposition. In order to avoid local optima, the TAO helps the NRBO to escape from the dilemma of local minima, and by adjusting the search path to maintain the global search capability, αₘₐₓ is gradually optimized to the optimal value.

Finally, through the iterative optimization of the NRBO combined with the minimum fuzzy entropy fitness function, an optimal value of αₘₐₓ can be accurately obtained, so as to ensure an optimal quality of an SVMD result and improve the accuracy and the robustness of signal processing.

The fuzzy entropy integrates a sample entropy and a fuzzy membership function to describe a signal complexity. By virtue of introducing the fuzzy membership function, the fuzzy entropy can more comprehensively account for the uncertainty of sample values, thereby providing a more accurate signal description. Assuming that the leakage magnetic field signal of a transformer winding measured by the magneto-optical sensor is an E-dimensional time series {l(t)=/(1), l(2), . . . , l(E)}, a time series D(i) is obtained after spatial reconstruction:

$$D ( i ) = [ l ( i ) , l ( i + 1 ) , … l ( i + a - 1 ) ] - {l}_{0} ( i ) \qquad ( 1 )$$

$${l}_{0} ( i ) = \frac{1}{a} {\sum }_{j = 0}^{a - 1} l ( i + j ) \qquad ( 2 )$$

where i=1, 2, . . . , E−a+1, and a denotes an embedding dimension; i and j denote index offsets of a time series; and l₀(i) denotes an average value;
next, a distance d between two time series D(i) and D(j) is defined in the following formula, which takes a maximum value of element-wise differences between the two time series:

$$\begin{matrix}{d}_{i , j}^{a} = d [ D ( i ) , D ( j ) ] \\ = {max}_{g = 0 , … , a - 1} \vert ( l ( i + g ) - {l}_{0} ( i ) - ( l ( j + g ) - {l}_{0} ( j ) ) \vert\end{matrix} \qquad ( 3 )$$

where d denotes the distance between the time series D(i) and D(j); and g denotes an index offset of the time series;
a similarity between the time series D(i) and D(j) may be calculated using the fuzzy membership function:

$${F}_{i , j}^{a} = exp [ - \frac{{( {d}_{i , j}^{a} )}^{2}}{p} ] \qquad ( 4 )$$

where p denotes a similarity tolerance, which generally takes 0.15 times the standard deviation of an original leakage magnetic field signal; i, j=1, 2, . . . , E−a+1, and i≠j;

$${ψ}^{a} ( p ) = \frac{1}{E - a + 1} {\sum }_{i = 1}^{E - a + 1} ( \frac{1}{E - a} {\sum }_{j = 1 , j \neq i}^{E - a + 1} {F}_{i , j}^{a} ) \qquad ( 5 )$$

where ψ^{a}(p) denotes a metric value of a fuzzy similarity of the time series under a scale a;
then, the expression of the fuzzy entropy FuzzyEn (a, p, E) is:

$$FuzzyEn ( a , p , e ) = ln {ψ}^{a} ( p ) - ln {ψ}^{a + 1} ( p ) \qquad ( 6 )$$

Upon calculation of the fuzzy entropy, the value of the entropy can be used to guide an optimization process of a maximum penalty factor αₘₐₓ. The value of the fuzzy entropy measures the complexity and the regularity after signal decomposition, for the purpose of achieving more accurate and ideal signal decomposition by minimizing the fuzzy entropy. Through an optimization algorithm of the NRBO, in each iteration, the decomposition result is first calculated according to the current αₘₐₓ, then the corresponding fuzzy entropy value is calculated and taken as the fitness function to adjust αₘₐₓ. In each iteration, the NRBO updates αₘₐₓ according to the current fuzzy entropy value and the NRSR, so that the fuzzy entropy decreases gradually and eventually converge to a minimum value. During this process, the TAO helps the algorithm to avoid local optimal solutions, thereby ensuring that a globally optimal max can be found. Through the continuous optimization of the fuzzy entropy, the NRBO finally determines the optimal αₘₐₓ, thereby optimizing the mode decomposition effect of the signal.

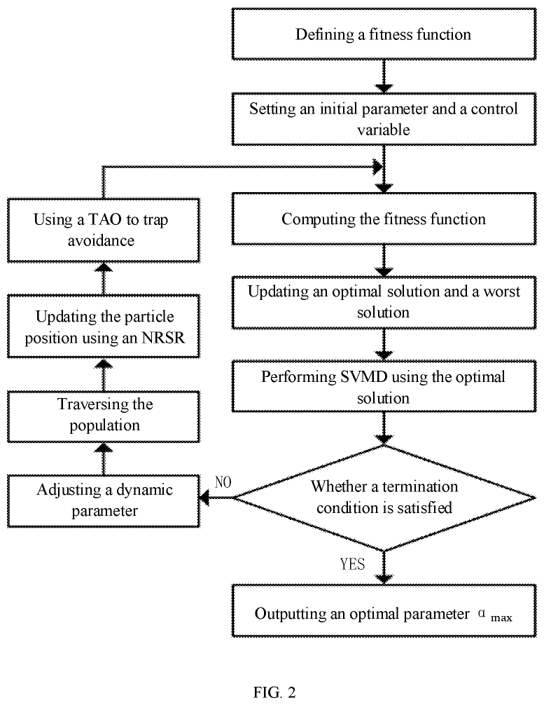

Step 2: performing, on the basis of the Step 1, an SVMD on a leakage magnetic field signal measured by a magneto-optical sensor. To sum up, the specific steps for determining the SVMD parameter αₘₐₓ via the NRBO method are illustrated in FIG. 2. In the Step 2, on the basis of Step 1, the SVMD is performed on the leakage magnetic field signal measured by the magneto-optical sensor.

On the basis of the Step 1, the SVMD is performed on the leakage magnetic field signal l(t) measured by the magneto-optical sensor using the optimized αₘₐₓ. Through the VMD, the SVMD algorithm divides l(t) into a plurality of mode functions. In each iteration, the SVMD updates the mode function by minimizing the difference between l(t) and the mode function, which is repeated continuously until convergence is achieved, and the finally obtained mode function can be used to reconstruct an original signal.

Some constraints are imposed during the extraction of the mode function to prevent a model from converging to a mode having been extracted, and a constraint model is as follows:

$$\{ \begin{matrix}{min}_{\{ {u}_{M} \} , \{ {ω}_{M} \} , \{ {l}_{r} \}} \{ α {J}_{1} + {J}_{2} + {J}_{3} \} \\ s . t . {\sum }_{k = 1}^{K} {u}_{M} ( t ) + {l}_{r} ( t ) = l ( t )\end{matrix} \qquad ( 7 )$$

where J₁, J₂ and J₃ are three constraint criteria; a is a parameter used to balance J₁, J₂ and J₃, and is obtained by Lagrange multiplication, with a value less than αₘₐₓ; u_{M} denotes an M-th mode component decomposed through the SVMD; ω_{M} denotes a center frequency of an M-th mode; lᵣ denotes a residual signal, i.e., an input signal excluding u_{M}; K denotes a total number of mode components; and u_{M} denotes the M-th mode component;

In order to solve Equation (7), an augmented Lagrangian function is constructed as follows by introducing a combination of a quadratic penalty coefficient and a Lagrange multiplier λ:

$$L ( \{ {u}_{M} \} , \{ {ω}_{M} \} , λ ) = α {J}_{1} + {J}_{2} + {J}_{3} + {‖ l ( t ) - ( {u}_{M} ( t ) + {l}_{u} ( t ) + {\sum }_{i = 1}^{M - 1} {u}_{t} ( t ) ) ‖}_{2}^{2} + 〈 λ ( t ) , l ( t ) - ( {u}_{M} ( t ) + {l}_{u} ( t ) + {\sum }_{i = 1}^{M - 1} {u}_{i} ( t ) ) 〉 \qquad ( 8 )$$

similar to the VMD, the issue of minimization in Equation (8) is solved iteratively using Parseval's identity and an alternating direction method of multipliers, and specifically

$${\hat{u}}_{M}^{n + 1} ( ω ) = \frac{\hat{l} ( ω ) + {{α}^{2} ( ω - {ω}_{M}^{n} )}^{4} {\hat{u}}_{M}^{n} ( ω ) + \frac{\hat{λ} ( ω )}{2}}{A [ 1 + 2 {α ( ω - {ω}_{M}^{n} )}^{2} + {\sum }_{i - 1}^{M - 1} \frac{1}{{{α}^{2} ( ω - {ω}_{i} )}^{4}} ]} \qquad ( 9 )$$

$$A = 1 + {{α}^{2} ( ω - {ω}_{M}^{n} )}^{4} \qquad ( 10 )$$

where û_{M}(ω) denotes a frequency spectrum of the mode; l(ω) denotes a frequency spectrum of the signal; n denotes the number of iterations; ω denotes a center frequency; and A denotes an intermediate variable;

Equation (11) is used to update the Lagrange multiplier:

$${\hat{λ}}^{n + 1} = {\hat{λ}}^{n} + τ [ \hat{l} ( ω ) - ( {\hat{u}}_{M}^{n + 1} ( ω ) + {l}_{u}^{n + 1} ( t ) + {\sum }_{i = 1}^{M - 1} {u}_{i}^{n + 1} ( ω ) ) ] \qquad ( 11 )$$

during the iteration, the center frequency and a bandwidth of an IMF are updated continuously until the following conditions are met:

$$\{ \begin{matrix}\frac{{‖ {\hat{u}}_{M}^{n + 1} - {\hat{u}}_{M}^{n} ‖}_{2}^{2}}{‖ {\hat{u}}_{M}^{n} ‖} < {ε}_{1} \\ {σ}^{2} - \frac{1}{T} {‖ ( l ( t ) - {\sum }_{m = 1 : M} {u}_{m} ( t ) ) ‖}_{2}^{2} / {σ}^{2} < {ε}_{2}\end{matrix} \qquad ( 12 )$$

where

$${u}_{M}^{n}$$

denotes an n-th update of the M-th mode; T denotes a dual ascent time step; ε₁ and ε₂ denote tolerances; and σ² denotes a noise variance.

After iteration and optimization by the SVMD algorithm, several mode components u_{M}(t) are finally obtained, which represent the independent components of the leakage magnetic field signal l(t) within different frequency ranges. After optimization and constraint processing, each mode function u_{M}(t) can accurately represent the features of the signal, thereby facilitating in-depth analysis and fault diagnosis of the leakage magnetic field signal of the transformer windings. However, some noise components may still remain unremoved after the SVMD, and particularly in the low-frequency part, the residual signal lᵣ(t) may contain unwanted noise. In order to further improve the signal quality, Step 3 will introduce the wavelet threshold method to process residual noise obtained after the SVMD.

Step 3: further processing residual noise in the signal in conjunction with a wavelet threshold method. The further processing residual noise in the signal in conjunction with a wavelet threshold method includes:

Although Gaussian white noise can be removed by optimizing the SVMD parameter using the NRBO, the periodic interferences within some specific frequency ranges or other non-Gaussian noise is not completely separated from the transformer leakage magnetic field signal. Therefore, by using the wavelet threshold method, it is possible to capture local features in the signal more effectively, process the residual noise, and further improve the signal quality.

A wavelet transform is performed on the mode components and the residual signal lᵣ(t) obtained through the SVMD in the Step 2, so as to obtain a wavelet coefficient. The wavelet transform can effectively decompose the signal into different frequency bands, so that the noise components in the signal can be separated more accurately. In order to better remove the noise, a soft-thresholding method is adopted for noise suppression, which is expressed as:

$${w}_{β , η}^{′} = [ \begin{matrix}sgn ( {w}_{β , η} ) ( \vert {w}_{β , η} \vert - θ ) & \vert {w}_{β , η} \vert \geq θ \\ 0 & \vert {w}_{β , η} \vert < θ\end{matrix} \qquad ( 13 )$$

where sgn denotes a signum function; β denotes a variation factor; θ denotes a threshold parameter, w_{β,η} denotes an original wavelet coefficient of the signal; and w′_{β,η} denotes a processed wavelet coefficient of the signal;
and the threshold parameter θ is expressed as:

$$θ = μ \sqrt{2 ln N} \qquad ( 14 )$$

$$μ = \frac{median ( \vert {w}_{1 , η} \vert )}{0.6475} \qquad ( 15 )$$

where μ denotes a noise standard deviation; N denotes a signal length; median denotes a median absolute deviation; and w_{1,η} denotes an η-th wavelet coefficient in a first layer.

After the threshold processing of the wavelet coefficient, an inverse wavelet transform is adopted to reconstruct the processed coefficient to a time-domain signal. This processing can remove most noise components and effectively retain important information in the signal, thereby improving the signal quality. After the processing with the wavelet threshold method, the finally obtained signal has higher accuracy and less noise compared with the original signal, making it suitable for further analysis and fault diagnosis.

Specifically, the mode components and the residual signal lᵣ(t) obtained through the SVMD are processed by in conjunction with the wavelet threshold method to obtain the processed wavelet coefficient of the signal. Next, an inverse wavelet transform is performed on the processed wavelet coefficient of the signal to obtain a time-domain signal, which is used for the fault diagnosis of the transformer. Specifically, the fault diagnosis of the transformer based on the time-domain signal includes the following steps.
(1) Obtaining a leakage magnetic field signal.
(2) Utilizing the advantages of the improved SVMD and the wavelet threshold method to perform denoising processing on the obtained leakage magnetic field signal.
(3) Establishing a transformer fault diagnosis model. Firstly, a fault feature database is constructed, and then signal feature matching and fault determination are conducted (specifically, for each fault, feature data corresponding to the fault is preset; after a time-domain signal is obtained, it is processed to obtain to-be-matched feature data, which is matched with the feature data corresponding to each fault, so as to obtain target feature data matching the to-be-matched feature data, and determine a fault corresponding to the target feature data as the currently existing fault);
(4) Using the data obtained in the step (2) to perform a fault diagnosis through step (3).

In an implementation of the present disclosure, in a power distribution system of a laboratory, a dry-type power distribution transformer with a voltage level of 400V and a capacity of 50 kVA (rated current of 10 A) has been in operation for 5 years, and recently there is slight abnormal noise during load fluctuations. In order to check the defects such as iron core multi-point grounding and a winding deformation (these defects will cause an abnormal leakage magnetic field), a fault diagnosis is carried out using a magnetic flux leakage detection technology combined with a time-domain signal processing method.

### 1. Signal Collection Phase

(1) Detection device: a magnetic flux leakage detector (with a detection accuracy of 0.1 mT and a sampling frequency of 1 kHz), equipped with flexible magnetic sensors. The measuring points are arranged at 10 feature positions on a winding surface to synchronously collect time-domain signals of the leakage magnetic field under no-load and rated load conditions.
(2) Signal collection operation: the detector is started, the sensors are moved along a preset path at a scanning speed of 0.2 m/s, the time-domain signals of the leakage magnetic field for each path are collected (the collection duration in each path is 10 seconds, which is corresponding to 10,000 sampling points), and the position coordinates of each path are recorded simultaneously.

### 2. Implementation of Time-Domain Signal Processing

The collected leakage magnetic field signals are denoised using the improved SVMD and the wavelet threshold method. The leakage magnetic field signals are decomposed into various mode components and residual signals; wavelet thresholding is applied to a noise-containing mode to retain the main feature components, and then an inverse wavelet transform is performed to reconstruct the signals.

### 3. Feature Extraction

### (1) Basic Statistical Feature Extraction

The mean, variance, skewness, and kurtosis of the preprocessed signals to preliminarily ascertain the potential presence of iron core defects within the abnormal area.

### (2) Waveform Index Extraction

A maximum peak value of the signals in abnormal area is identified, and a peak factor, a waveform factor, and a zero-crossing rate (i.e., the corresponding to-be-matched data) are calculated.

### 4. Fault Diagnosis and Judgment

(1) Matching with the Fault Feature Database

The 400V/50 kVA transformer fault database is called (including the feature parameters of the defect such as the iron core multi-point grounding and the winding deformation (specifically, the peak factor, the waveform factor, and the zero-crossing rate determined for each fault)). The extracted feature parameters are compared with the database, and it is found that the matching degree with the feature of “iron core multi-point grounding” reaches 92%.

### (2) Defect Localization and Report Generation

In combination with the coordinates of the detection path, it is determined that the defect is located at the position corresponding to “area 2-path 2” (a lower-middle part of an internal Phase A winding).

Through this process, the iron core multi-point grounding defect in the 400V/50 kVA transformer is successfully localized, which prevents the problems such as transformer overheating and increased energy consumption caused by the expansion of the defect. After maintenance, the transformer resumes the normal operation, the abnormal noise disappears during load fluctuations, and the leakage magnetic field signal returns to the normal range.

What is claimed is:

1. A method for measuring transformer leakage magnetic field signals based on improved Successive Variational Mode Decomposition (SVMD) combined with a wavelet threshold method, comprising:
Step 1: determining a parameter of the SVMD through a Newton-Raphson-Based Optimizer (NRBO);
Step 2: performing, on the basis of the Step 1, an SVMD on a leakage magnetic field signal measured by a magneto-optical sensor; and
Step 3: further processing residual noise in the signal in conjunction with a wavelet threshold method.

2. The method for measuring transformer leakage magnetic field signals based on improved SVMD combined with a wavelet threshold method according to claim 1, wherein in the Step 1, a Newton-Raphson Search Rule (NRSR) is used to calculate a gradient and second-order information of a fitness function, wherein the fitness function adopts minimum fuzzy entropy, which serves as an objective function for optimization and is calculated in each iteration, a fuzzy entropy, as the fitness function, is capable of measuring the fuzziness degree of a signal decomposition result, and a minimized entropy value represents an optimal quality of decomposition; in each iteration, the NRBO adjust αₘₐₓ according to a current fitness function value through the NRSR, so as to improve an accuracy of the decomposition result; finally, through the iterative optimization of the NRBO combined with the minimum fuzzy entropy fitness function, an optimal value of αₘₐₓ is obtained, so as to ensure an optimal quality of an SVMD result and improve the accuracy and the robustness of signal processing.

3. The method for measuring transformer leakage magnetic field signals based on improved SVMD combined with a wavelet threshold method according to claim 2, wherein in the Step 1, the fuzzy entropy integrates a sample entropy and a fuzzy membership function to describe a signal complexity, wherein a more accurate signal description is provided by virtue of introducing the fuzzy membership function; assuming that the leakage magnetic field signal of a transformer winding measured by the magneto-optical sensor is an E-dimensional time series {l(t)=l(1), l(2), . . . , l(E)}, a time series D(i) is obtained after spatial reconstruction:
$$D ( i ) = [ l ( i ) , l ( i + 1 ) , … l ( i + a - 1 ) ] - {l}_{0} ( i ) \qquad ( 1 )$$
$${l}_{0} ( i ) = \frac{1}{a} {\sum }_{j = 0}^{a - 1} l ( i + j ) \qquad ( 2 )$$
where i=1, 2, . . . , E−a+1, and a denotes an embedding dimension; i and j denote index offsets of a time series; and l₀(i) denotes an average value;
next, a distance d between two time series D(i) and D(j) is defined in the following formula, which takes a maximum value of element-wise differences between the two time series:
$$\begin{matrix}{d}_{i , j}^{a} = d [ D ( i ) , D ( j ) ] \\ = {max}_{g = 0 , … , a - 1} \vert ( l ( i + g ) - {l}_{0} ( i ) - ( l ( j + g ) - {l}_{0} ( j ) ) \vert\end{matrix} \qquad ( 3 )$$
where d denotes the distance between the time series D(i) and D(j); and g denotes an index offset of the time series;
a similarity between the time series D(i) and D(j) is calculated using the fuzzy membership function:
$${F}_{i . j}^{a} = exp [ - \frac{{( {d}_{i . j}^{a} )}^{2}}{p} ] \qquad ( 4 )$$
where p denotes a similarity tolerance, which generally takes 0.15 times the standard deviation of an original leakage magnetic field signal; i, j=1, 2, . . . , E−a+1, and i≠j;
$${ψ}^{a} ( p ) = \frac{1}{E - a + 1} {\sum }_{i = 1}^{E - a + 1} ( \frac{1}{E - a} {\sum }_{j = 1 , j \neq i}^{E - a + 1} {F}_{i , j}^{a} ) \qquad ( 5 )$$
where ψ^{a}(p) denotes a metric value of a fuzzy similarity of the time series under a scale a;
then, the expression of the fuzzy entropy FuzzyEn (a, p, E) is:
$$FuzzyEN ( a , p , E ) = ln {ψ}^{a} ( p ) - ln {ψ}^{a + 1} ( p ) \qquad ( 6 )$$
upon calculation of the fuzzy entropy, the value of the entropy is used to guide an optimization process of a maximum penalty factor αₘₐₓ; through an optimization algorithm of the NRBO, in each iteration, the decomposition result is first calculated according to the current αₘₐₓ, then the corresponding fuzzy entropy value is determined and taken as the fitness function to adjust αₘₐₓ, wherein in each iteration, the NRBO updates αₘₐₓ according to the current fuzzy entropy value and the NRSR, so that the fuzzy entropy decreases gradually and eventually converge to a minimum value.

4. The method for measuring transformer leakage magnetic field signals based on improved SVMD combined with a wavelet threshold method according to claim 1, wherein in the Step 2, the performing, on the basis of the Step 1, an SVMD on the leakage magnetic field signal measured by the magneto-optical sensor comprises: performing an SVMD on the leakage magnetic field signal l(t) measured by the magneto-optical sensor using the optimized αₘₐₓ.

5. The method for measuring transformer leakage magnetic field signals based on improved SVMD combined with a wavelet threshold method according to claim 4, wherein in the Step 2, the SVMD divides l(t) into a plurality of mode functions; in each iteration, the SVMD updates the mode function by minimizing the difference between l(t) and the mode function, which is repeated continuously until convergence is achieved, and the finally obtained mode function is used to reconstruct an original signal.

6. The method for measuring transformer leakage magnetic field signals based on improved SVMD combined with a wavelet threshold method according to claim 5, wherein in the Step 2, some constraints are imposed during the extraction of the mode function to prevent a model from converging to a mode having been extracted, and a constraint model is as follows:
$$\{ \begin{matrix}{min}_{\{ {u}_{M} \} , \{ {ω}_{M} \} , \{ {l}_{r} \}} \{ α {J}_{1} + {J}_{2} + {J}_{3} \} \\ s . t . {\sum }_{k = 1}^{K} {u}_{M} ( t ) + {l}_{r} ( t ) = l ( t )\end{matrix} \qquad ( 7 )$$
where J₁, J₂ and J₃ are three constraint criteria; a is a parameter used to balance J₁, J₂ and J₃, and is obtained by Lagrange multiplication, with a value less than αₘₐₓ; u_{M} denotes an M-th mode component decomposed through the SVMD; ω_{M} denotes a center frequency of an M-th mode; and lᵣ denotes a residual signal, i.e., an input signal excluding u_{M};
an augmented Lagrangian function is constructed as follows by introducing a combination of a quadratic penalty coefficient and a Lagrange multiplier λ:
$$L ( \{ {u}_{M} \} , \{ {ω}_{M} \} , λ ) = α {J}_{1} + {J}_{2} + {J}_{3} + {‖ l ( t ) - ( {u}_{M} ( t ) + {l}_{u} ( t ) + {\sum }_{i = 1}^{M - 1} {u}_{i} ( t ) ) ‖}_{2}^{2} + 〈 λ ( t ) , l ( t ) - ( {u}_{M} ( t ) + {l}_{u} ( t ) + {\sum }_{i = 1}^{M - 1} {u}_{i} ( t ) ) 〉 \qquad ( 8 )$$
similar to a Variational Mode Decomposition (VMD), the issue of minimization in Equation (8) is solved by iteratively using a Parseval's identity and an alternating direction method of multipliers, and specifically
$${\hat{u}}_{M}^{n + 1} ( ω ) = \frac{\hat{l} ( ω ) + {{α}^{2} ( ω - {ω}_{M}^{n} )}^{4} {\hat{u}}_{M}^{n} ( ω ) + \frac{\hat{λ} ( ω )}{2}}{A [ 1 + 2 {α ( ω - {ω}_{M}^{n} )}^{2} + {\sum }_{i - 1}^{M - 1} \frac{1}{{{α}^{2} ( ω - {ω}_{i} )}^{4}} ]} \qquad ( 9 )$$
$$A = 1 + {{α}^{2} ( ω - {ω}_{M}^{n} )}^{4} \qquad ( 10 )$$
where û_{M}(ω) denotes a frequency spectrum of the mode; l(ω) denotes a frequency spectrum of the signal; and n denotes the number of iterations;
Equation (11) is used to update the Lagrange multiplier:
$${\hat{λ}}^{n + 1} = {\hat{λ}}^{n} + τ [ \hat{l} ( ω ) - ( {\hat{u}}_{M}^{n + 1} ( ω ) + {l}_{u}^{n + 1} ( t ) + {\sum }_{i = 1}^{M - 1} {u}^{n + 1} ( ω ) ) ] \qquad ( 11 )$$
during the iteration, the center frequency and a bandwidth of an intrinsic mode function are updated continuously until the following conditions are met:
$$\{ \begin{matrix}\frac{{‖ {\hat{u}}_{M}^{n + 1} - {\hat{u}}_{M}^{n} ‖}_{2}^{2}}{‖ {\hat{u}}_{M}^{n} ‖} < {ε}_{1} \\ {σ}^{2} - \frac{1}{T} {‖ ( l ( t ) - {\sum }_{m = 1 : M} {u}_{m} ( t ) ) ‖}_{2}^{2} / {σ}^{2} < {ε}_{2}\end{matrix} \qquad ( 12 )$$
where
$${u}_{M}^{n}$$
denotes an n-th update or the M-th mode; T denotes a dual ascent time step; ε₁ and ε₂ denote tolerances; and σ² denotes a noise variance.

7. The method for measuring transformer leakage magnetic field signals based on improved SVMD combined with a wavelet threshold method according to claim 1, wherein in the Step 3, the further processing residual noise in the signal in conjunction with the wavelet threshold method comprises: performing a wavelet transform on the mode components and a residual signal lᵣ(t) obtained through the SVMD in the Step 2, so as to obtain a wavelet coefficient, and the wavelet transform is capable of effectively decomposing the signal into different frequency bands; and a soft-thresholding method is adopted for noise suppression, which is expressed as:
$${w}_{β , η}^{′} = \{ \begin{matrix}sgn ( {w}_{β , η} ) ( \vert {w}_{β , η} \vert - θ ) & \vert {w}_{β , η} \vert \geq θ \\ 0 & \vert {w}_{β , η} \vert < θ\end{matrix} \qquad ( 13 )$$
where sgn denotes a signum function; β denotes a variation factor; θ denotes a threshold parameter; w_{β,η} denotes an original wavelet coefficient of the signal; and w′_{β,η} denotes a processed wavelet coefficient of the signal;
wherein the threshold parameter θ is expressed as:
$$θ = μ \sqrt{2 ln N} \qquad ( 14 )$$
$$μ = \frac{median ( \vert {w}_{1 , η} \vert )}{0.6475} \qquad ( 15 )$$
where μ denotes a noise standard deviation; N denotes a signal length; median denotes a median absolute deviation; and w_{1,η} denotes an η-th wavelet coefficient in a first layer.
